(19) United States
(12) Patent Application Publication
(10) Pub. No.: US 2025/0076774 A1
(43) Pub. Date: Mar. 6, 2025

(54) LITHOGRAPHY APPARATUS, STAGE APPARATUS, AND ARTICLE MANUFACTURING METHOD

(71) Applicant: CANON KABUSHIKI KAISHA, Tokyo (JP)

(72) Inventor: NAOSUKE NISHIMURA, Saitama (JP)

(21) Appl. No.: 18/804,436

(22) Filed: Aug. 14, 2024

(30) Foreign Application Priority Data
Aug. 28, 2023 (JP) 2023-138202

(51) Int. Cl. G03F 7/00; G03F 9/00

(52) U.S. Cl. CPC G03F 7/70775; G03F 7/70725; G03F 9/7042

(57) ABSTRACT

A lithography apparatus that transfers a pattern of an original to a substrate, includes a stage mechanism including a stage configured to hold the substrate, and an encoder system including an encoder head and an encoder scale. The stage includes a scale holding portion configured to hold the encoder scale by an attraction force. The scale holding portion includes a plurality of attractors capable of individually controlling attraction.

### BACKGROUND OF THE INVENTION

### Field of the Invention

The present invention relates to a lithography apparatus, a stage apparatus, and an article manufacturing method.

### Description of the Related Art

Lithography apparatuses such as an imprint apparatus and an exposure apparatus can be configured to transfer the pattern of an original to a plurality of shot regions of a substrate. The imprint apparatus brings an original into contact with an imprint material arranged on a substrate and then cures the imprint material, thereby transferring the pattern of the original to the substrate. The exposure apparatus projects the pattern of an original to a photoresist applied to a substrate and exposes the photoresist to light, thereby transferring the pattern of the original as a latent image to the photoresist. To transfer the pattern of an original to a plurality of shot regions of a substrate, a stage holding the substrate can be feedback-controlled. In the feedback control, while the position of the stage is measured using a measurement device such as an encoder, it is controlled based on the difference between the target position and the measurement value.

An encoder system can include, for example, an encoder scale fixed to a stage, and an encoder head arranged to face the encoder scale. To improve the article manufacturing throughput, the stage can be driven at a high acceleration to generate heat by a motor that drives the stage, and deform the stage by the heat. The encoder scale fixed to the stage can be deformed under the influence of deformation of the stage, decreasing the measurement accuracy of the position of the stage.

### SUMMARY OF THE INVENTION

The present invention provides a technique advantageous for suppressing a decrease in the measurement accuracy of the position of a stage caused by deformation of the stage.

One of aspects of the present invention provides a lithography apparatus that transfers a pattern of an original to a substrate, comprising: a stage mechanism including a stage configured to hold the substrate; and an encoder system including an encoder head and an encoder scale, wherein the stage includes a scale holding portion configured to hold the encoder scale by an attraction force, and the scale holding portion includes a plurality of attractors capable of individually controlling attraction.

Further features of the present invention will become apparent from the following description of exemplary embodiments with reference to the attached drawings.

### BRIEF DESCRIPTION OF THE DRAWINGS

FIG. 1 is a view showing the arrangement of a lithography apparatus;

FIG. 2 is a view taken along a line A-A in FIG. 1;

FIG. 3 is a view taken along a line B-B in FIG. 1;

FIG. 4 is a sectional view taken along a line C-C in FIG. 2;

FIGS. 5A and 5B are a plan view of a stage mechanism, and a sectional view take along a line D-D, respectively;

FIG. 6 is a flowchart exemplifying the operation of the lithography apparatus constituted as an imprint apparatus;

FIG. 7 shows views exemplifying a method of controlling the operation states of a plurality of attractors;

FIG. 8 is a view exemplifying the operation states of the plurality of attractors;

FIG. 9 shows views exemplifying processing for transferring a pattern to a central shot region (ith shot region) out of a plurality of shot regions of a substrate;

FIG. 10 shows views exemplifying processing for transferring a pattern to the (i+1)th shot region that is a shot region next to the ith shot region (central shot region of a substrate 1);

FIG. 11 is a view exemplifying a non-attraction region;

FIGS. 12A and 12B are views showing other layout examples of the plurality of attractors or non-attraction regions;

FIGS. 13A to 13C are views showing a modification of an encoder system;

FIGS. 14A and 14B are views showing the first and second arrangement examples of the second embodiment, respectively; and

FIG. 15 is a view showing the third embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted. In this specification and the drawings, a direction is explained in accordance with the XYZ coordinate system. In the XYZ coordinate system, the Z-axis is defined to be parallel to the vertical direction. The X, Y, and Z directions are parallel to the X-, Y-, and Z-axes, respectively. The θ direction is a rotational direction about the Z-axis. The X and Y directions are parallel to an X-Y plane. Driving in the X and Y directions means driving in the X direction, driving in the Y direction, or driving in the X and Y directions.

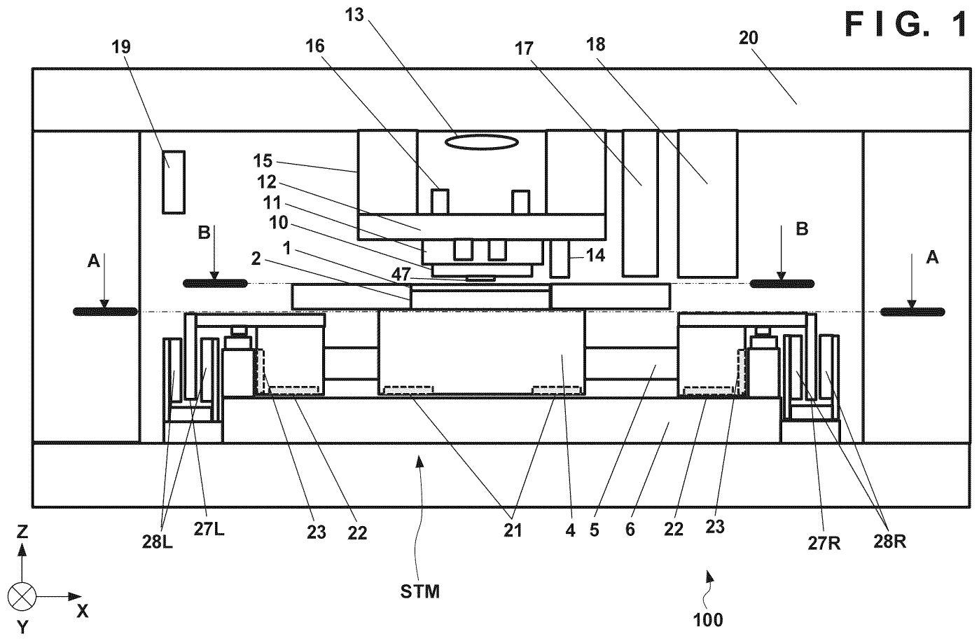

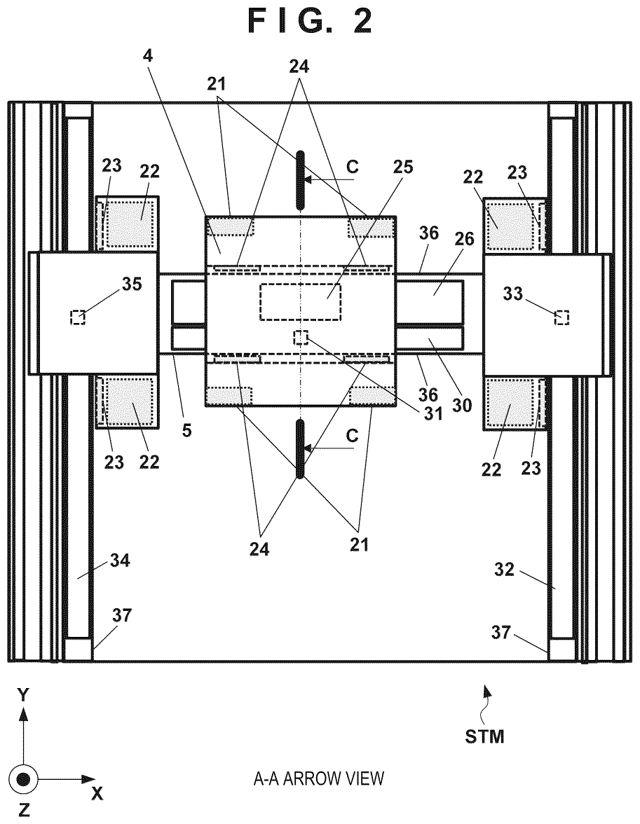

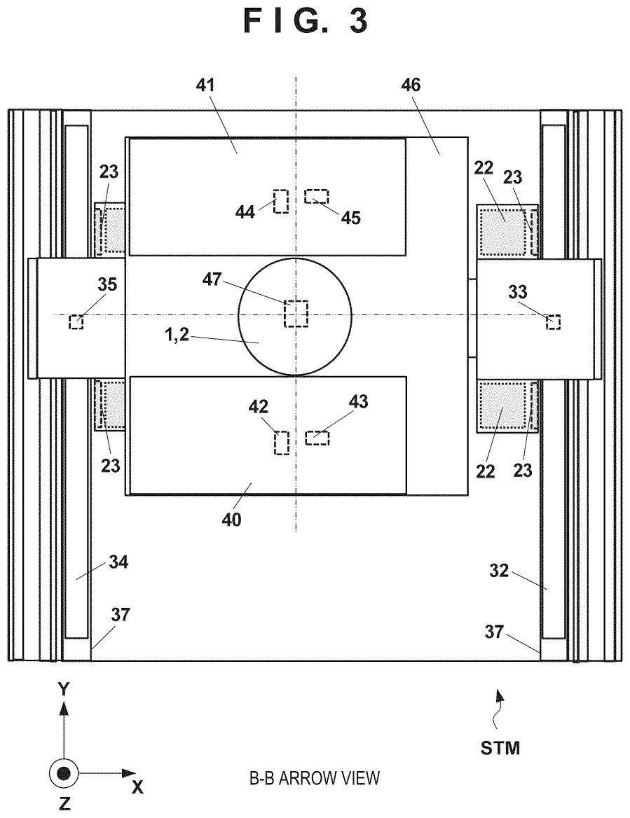

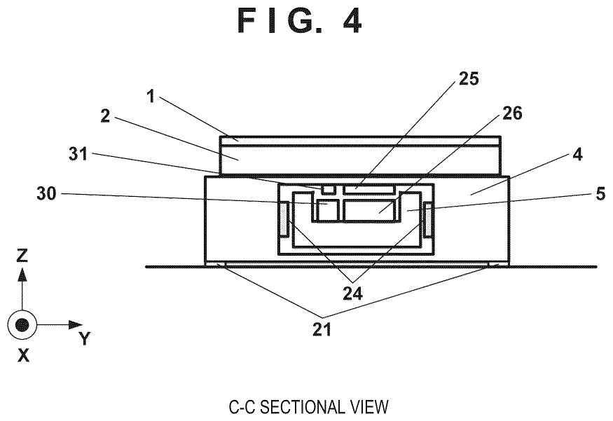

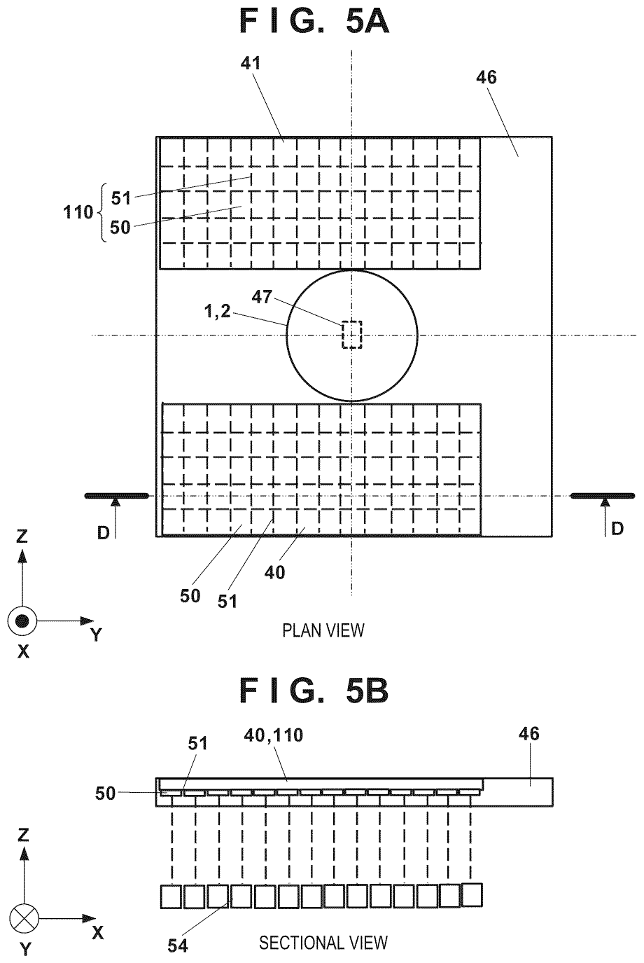

A lithography apparatus 100 and a stage apparatus STM according to the first embodiment will be explained with reference to FIGS. 1, 2, 3, and 4. The stage apparatus STM may be understood as a stage mechanism. FIG. 1 is a view showing the arrangement of the lithography apparatus 100. FIG. 2 is a view taken along a line A-A in FIG. 1. FIG. 3 is a view taken along a line B-B in FIG. 1. FIG. 4 is a sectional view taken along a line C-C in FIG. 2. FIG. 5A is a plan view of the stage mechanism STM, and FIG. 5B is a sectional view take along a line D-D in FIG. 5A. An example in which the lithography apparatus 100 is constituted as an imprint apparatus will be explained here. However, the lithography apparatus 100 may be constituted as an exposure apparatus that projects the pattern of an original to a substrate 1 by a projection optical system, thereby transferring the pattern of the original to the substrate. The imprint apparatus serving as the lithography apparatus 100 brings a mold 10 serving as an original into contact with an imprint material arranged on the substrate 1 and then cures the imprint material, thereby transferring the pattern of the mold 10 to (the imprint material on) the substrate 1. The substrate 1 generally has a plurality of shot regions, and the pattern of the mold 10 is transferred to each shot region.

As the imprint material, a curable composition (to be also referred to as a resin in an uncured state) to be cured by receiving curing energy is used. As the curing energy, an electromagnetic wave or heat can be used. The electromagnetic wave can be, for example, light selected from the wavelength range of 10 nm (inclusive) to 1 mm (inclusive), for example, infrared light, a visible light beam, or ultraviolet light. The curable composition can be a composition cured by light irradiation or heating. Among compositions, a photo-curable composition cured by light irradiation contains at least a polymerizable compound and a photopolymerization initiator, and may further contain a nonpolymerizable compound or a solvent, as needed. The nonpolymerizable compound is at least one material selected from the group consisting of a sensitizer, a hydrogen donor, an internal mold release agent, a surfactant, an antioxidant, and a polymer component. The imprint material can be arranged on the substrate in the form of droplets or in the form of an island or film formed by connecting a plurality of droplets. The imprint material may be supplied onto the substrate in the form of a film by a spin coater or a slit coater. The viscosity (the viscosity at 25° C.) of the imprint material can be, for example, 1 mPa·s (inclusive) to 100 mPa·s (inclusive). As the material of the substrate, for example, glass, a ceramic, a metal, a semiconductor (Si, GaN, SiC, or the like), a resin, or the like can be used. A member made of a material different from the substrate may be provided on the surface of the substrate, as needed. The substrate is, for example, a silicon wafer, a semiconductor compound wafer, or silica glass.

The lithography apparatus 100 includes the stage mechanism STM including a stage 4 (X-Y movable portion) that holds the substrate 1. The stage 4 includes a chuck device 2 that chucks the substrate 1. The chuck device 2 can be, for example, a vacuum chuck or an electrostatic chuck. The stage mechanism STM includes an X-Y movable portion as the stage 4 that can move in the X and Y directions, a Y movable portion 5 that can move in the Y direction, and a stage base 6 that supports the stage 4 and the Y movable portion 5. The stage 4 holds the substrate 1 and is arranged to be movable in the X and Y directions while using the upper surface of the stage base 6 as a guide surface. The stage 4 can float on the guide surface of the stage base 6 by air guides 21. The stage 4 is guided by the Y movable portion 5 via lateral air guides 24, and driven in the X direction by an X linear motor formed from an X linear motor movable portion 25 and an X linear motor stationary portion 26. An X encoder scale 30 can be arranged at the Y movable portion 5, and an X encoder head 31 can be provided on the stage 4 so as to face the X encoder scale 30. The X encoder scale 30 and the X encoder head 31 constitute an X encoder that measures the position of the stage 4 in the X direction with respect to the Y movable portion 5.

The Y movable portion 5 can have a guide surface 36 that guides the stage 4 so that the stage 4 can move in the X direction with respect to the Y movable portion 5. The X linear motor stationary portion 26 can be provided on the Y movable portion 5. The Y movable portion 5 can be guided by the stage base 6 via bottom air guides 22, guided by first and second Y guides 37 via lateral air guides 23, and driven in the Y direction by first and second Y linear motors. The first Y linear motor can be constituted by a Y linear motor movable portion 27R provided at the Y movable portion 5, and Y linear motor stationary portions 28R fixed to the stage base 6. The second Y linear motor can be constituted by a Y linear motor movable portion 27L provided at the Y movable portion 5, and Y linear motor stationary portions 28L fixed to the stage base 6.

The position of the Y movable portion 5 in the Y direction can be measured by first and second Y encoders. The first Y encoder can be constituted by a Y encoder scale 32 provided at the first Y guide 37, and a Y encoder head 33 provided at the Y movable portion 5 so as to face the Y encoder scale 32. The second Y encoder can be constituted by a Y encoder scale 34 provided at the second Y guide 37, and a Y encoder head 35 provided at the Y movable portion 5 so as to face the Y encoder scale 34.

The first and second Y encoders can measure the position of the Y movable portion 5 in the Y direction and its rotation in the 0 direction with respect to the stage base 6. The position of the Y movable portion 5 in the Y direction with respect to the stage base 6 can be detected based on a measurement value obtained by either of the first and second Y encoders or based on both of the first and second Y encoders. In the latter case, the position of the Y movable portion 5 in the Y direction with respect to the stage base 6 can be detected based on the average value of the measurement values of both of the first and second Y encoders. Alternatively, the position of the Y movable portion 5 in the Y direction with respect to the stage base 6 can be detected based on the measurement values of both of the first and second Y encoders, and the measurement value of the X encoder.

The rotation angle of the Y movable portion 5 in the 0 direction with respect to the stage base 6 can be specified based on the difference between the measurement values of the first and second Y encoders and the interval between the first and second Y encoders. That is, one X encoder and two Y encoders can be used to measure the position of the stage 4 with respect to the stage base 6 about three horizontal axes (a position in the X direction, a position in the Y direction, and a rotation angle in the θ direction).

The mold 10 has a pattern region 47 having a pattern to be transferred to the substrate 1, and is held by a mold head 11 provided on a mold stage 12. The mold stage 12 can be driven by an actuator 15 in at least the Z direction. The actuator 15 can drive the mold stage 12 so that the mold 10 is pressed against an imprint material on the substrate 1 and separated from the imprint material on the substrate 1. The actuator 15 may drive the mold stage 12 so as to adjust the tilt (rotation about the X-axis and rotation about the Y-axis) of the mold stage 12 (mold 10).

The mold stage 12 and the mold head 11 can have openings (not shown) through which curing light (for example, ultraviolet light) emitted from a light source (not shown) through a collimator lens 13 passes. On the mold stage 12, a load cell may be arranged to detect a press force when the mold 10 is pressed against an imprint material on the substrate 1. The lithography apparatus 100 may include a gap measurement sensor 14 for measuring the height of the substrate 1 held by the stage 4.

The lithography apparatus 100 can include a Through The Mold (TTM) alignment detection system 16 to align the mold 10 with the substrate 1. The alignment detection system 16 can be arranged on the mold stage 12. The alignment detection system 16 can include an optical system and imaging system for detecting an alignment mark formed on the mold 10, a reference mark (not shown) arranged on the stage 4, an alignment mark formed on the substrate 1, and the like. The alignment detection system 16 can detect relative misalignments between the alignment mark of the substrate 1 and that of the mold 10 in the X and Y directions in a state in which the mold 10 and the imprint material on the substrate 1 held by the stage 4 contact each other.

The lithography apparatus 100 can include a supply portion 17. The supply portion 17 can be constituted by a dispenser head including a nozzle that drops an imprint material. The supply portion 17 has a function of supplying, applying, or arranging an imprint material to the respective shot regions of the substrate 1. The supply portion 17 employs, for example, a piezo-jet method or a micro-solenoid method, and supplies a small volume of imprint material onto the substrate 1. The imprint material can be applied onto the substrate 1 by moving the stage 4 while discharging the imprint material from the supply portion 17.

The lithography apparatus 100 may include an off-axis detection system 18. The off-axis detection system 18 can be supported by a support top plate 20. The off-axis detection system 18 can include an optical system and imaging system for detecting a reference mark (not shown) arranged on the stage 4, the alignment mark of the substrate 1, and the like without the intervention of the mold 10. The off-axis detection system 18 can detect the position of the alignment mark of the substrate 1 with respect to the reference mark of the stage 4. In the lithography apparatus 100, the positional relationship between the mold 10 and the stage 4 can be obtained by the alignment detection system 16, and the positional relationship between the stage 4 and the alignment mark of the substrate 1 can be obtained by the off-axis detection system 18. Based on these positional relationships, relative alignment between the mold 10 and the substrate 1 can be performed.

The lithography apparatus 100 can include a controller 19. The controller 19 can control the operation of the lithography apparatus 100. The controller 19 can be constituted by, for example, a Programmable Logic Device (PLD) such as a Field Programmable Gate Array (FPGA), an Application Specific Integrated Circuit (ASIC), a program-installed general-purpose or dedicated computer, or a combination of all or some of them.

The lithography apparatus 100 includes an encoder system as the second measurement system that measures relative positions between the mold head 11 and the stage 4 about three axes, in addition to the first measurement system that measures relative positions between the stage base 6 and the stage 4 about three axes. The encoder system serving as the second measurement system can include, for example, encoder scales 40 and 41, and encoder heads 42, 43, 44, and 45.

A purge plate 46 is mounted on the stage 4, and the height of the upper surface of the purge plate 46 is equal to or slightly lower than that of the substrate 1. The purge plate 46 has two recesses, and the encoder scales 40 and 41 are arranged in the two recesses, respectively. Similar to the purge plate 46, the heights of the upper surfaces of the encoder scales 40 and 41 are substantially equal to or slightly lower than that of the substrate 1.

The encoder scale 40 has a diffraction grating for measurement in the X direction and a diffraction grating for measurement in the Y direction. The encoder scale 40, and the encoder heads 42 and 43 provided at the mold head 11 constitute the first encoder that measures relative positions between the mold head 11 and the stage 4 in the X and Y directions. The encoder heads 42 and 43 are arranged by a rotation of 90° between them, and can simultaneously measure the X direction measurement diffraction grating and Y direction measurement diffraction grating of the encoder scale 40. For example, the encoder head 42 measures the X direction measurement diffraction grating provided at the encoder scale 40, and the encoder head 43 measures the Y direction diffraction grating provided at the encoder scale 40.

Similarly, the encoder scale 41 has a diffraction grating for measurement in the X direction and a diffraction grating for measurement in the Y direction. The encoder scale 41, and the encoder heads 44 and 45 provided at the mold head 11 constitute the second encoder that measures relative positions between the mold head 11 and the stage 4 in the X and Y directions. The encoder heads 44 and 45 are arranged by a rotation of 90° between them, and can simultaneously measure the X direction measurement diffraction grating and Y direction measurement diffraction grating of the encoder scale 41. For example, the encoder head 44 measures the X direction measurement diffraction grating provided at the encoder scale 41, and the encoder head 45 measures the Y direction diffraction grating provided at the encoder scale 41.

Based on outputs from the first and second encoders, relative positions between the mold head 11 and the stage 4 can be measured about three axes. For example, a relative position between the mold head 11 and the stage 4 in the X direction can be detected based on either of two measurement values in the X direction obtained by the encoder heads 43 and 45. Alternatively, a relative position between the mold head 11 and the stage 4 in the X direction can be detected based on the average value of two measurement values in the X direction. A relative position between the mold head 11 and the stage 4 in the θ direction can be obtained by dividing, by the interval between the two encoder heads 43 and 45, the difference between two measurement values in the X direction obtained by the encoder heads 43 and 45. Also, a relative position between the mold head 11 and the stage 4 in the Y direction can be detected based on either of two measurement values in the Y direction obtained by the encoder heads 43 and 45. Alternatively, a relative position between the mold head 11 and the stage 4 in the Y direction can be detected based on the average value of two measurement values in the Y direction.

The cycle directions of the X direction measurement diffraction gratings and Y direction measurement diffraction gratings respectively provided at the encoder scales 40 and 41 may coincide with each other in the X and Y directions or cross each other at, for example, 45° in the X and Y directions. In the former case, the output values of the encoder heads 42 to 45 provide measurement values in the X or Y direction. In the latter case, measurement values in the X and Y directions can be obtained by processing the output values of the encoder heads 42 to 45.

FIG. 2 shows a method of fixing the purge plate 46 (stage 4) and the encoder scales 40 and 41. FIG. 5A is a plan view of the stage 4, and FIG. 5B is a sectional view take along a line D-D in FIG. 5A.

As shown in FIG. 5A, the encoder scale 41 can be held by a scale holding portion 110 of the purge plate 46. Although not shown, the encoder scale 41 can be held by a scale holding portion having an arrangement similar to that of the scale holding portion 110. The scale holding portion 110 holds the encoder scale 40 by an attraction force. The attraction force can be, for example, a vacuum attraction force, an electrostatic attraction force, or an electromagnetic attraction force. The scale holding portion 110 can be a recess dented from the uppermost surface of the purge plate 46. At the scale holding portion 110, a plurality of attractors 50 that are separated by banks 51 at the same size as that of the shot region. Each attractor 50 is a region where an attraction force for locally attracting the encoder scale 40 is generated. The attractors 50 can be configured to individually control attractions.

An attraction controller 54 can be provided for each attractor 50. In other words, a plurality of attraction controllers 54 can be provided so as to assign one attraction controller 54 to one attractor 50. Each attraction controller 54 controls the operation state of the attractor 50 to which the attraction controller 54 is assigned. The attraction controllers 54 can be individually controlled by the controller 19. The controller 19 can be configured to individually control the operation states of the respective attractors 50. This can be achieved by individually controlling the attraction controllers 54 by the controller 19. The controller 19 can be configured to control the operation states of the respective attractors 50 in accordance with the position of a shot region where the pattern of an imprint material (curing composition) is formed, out of a plurality of shot regions of the substrate 1. For example, the controller 19 can be configured to control, of the plurality of attractors 50, the attractor 50 facing at least one of the encoder heads 42 to 45 to be in a non-attraction state. Alternatively, the controller 19 may control the attraction force of the attractor 50 facing at least one of the encoder heads 42 to 45, out of the plurality of attractors 50, to be weaker than the attraction force of the remaining attractors 50. This can be implemented by providing each attraction controller 54 with a function of adjusting the attraction force. Note that the concept of controlling the attraction force of the given attractor 50 to be weaker than that of the remaining attractors 50 includes controlling the operation state of the given attractor 50 to be the non-attraction state, and that of the remaining attractors 50 to be the attraction state. The arrangement capable of individually controlling attractions by the plurality of attractors 50 yields various degrees of freedom, in addition to the above example.

For example, the controller 19 can control the attractor 50 selected from the plurality of attractors 50 to be in the non-attraction state, and the remaining attractors 50 to be in the attraction state. The selected attractor 50 can be, of the plurality of attractors 50, an attractor facing the encoder head in a predetermined period. The selected attractor may be, of the plurality of attractors 50, the attractor 50 arranged in a region including a region facing the encoder head in a predetermined period. Alternatively, the controller 19 can control the attraction force of the attractor 50 selected from the plurality of attractors 50 to be weaker than that of the remaining attractors. The selected attractor may be, of the plurality of attractors 50, the attractor 50 arranged in a region including a region facing the encoder head in a predetermined period. Alternatively, in accordance with the lapse of time or the operation of the lithography apparatus 100, the controller 19 may change the attractor 50 controlled to be in the attraction state and the attractor 50 controlled to be in the non-attraction state. These control operations can contribute to reduction of deformation of the encoder scales 40 and 41.

In an example, each attractor 50 can be configured to locally attract the encoder scale 40 by forming a reduced pressure state lower than atmospheric pressure. Such attraction can be defined as vacuum attraction. Each attraction controller 54 can control the attractor 50, to which the attraction controller 54 is assigned, to be in the reduced pressure state so that the attractor 50 attracts the encoder scale 40, and release the attractor 50 to air so as to cancel the attraction by the attractor 50, to which the attraction controller 54 is assigned. The attraction controller 54 can include, for example, a valve that connects the attractor 50 to a reduced pressure source or reduced pressure line, or provides atmospheric pressure to the attractor 50. The attractors 50 can be isolated from each other by, for example, the separation walls 51.

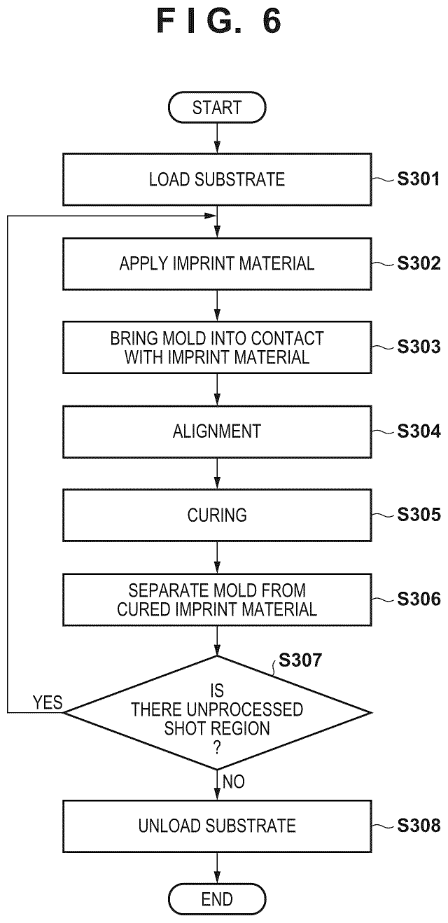

FIG. 6 exemplifies the operation of the lithography apparatus 100 constituted as an imprint apparatus. The operation exemplified in FIG. 6 is controlled by the controller 19. In step S301, the substrate 1 is loaded to the stage 4, and held by the stage 4 (more specifically, the chuck device 2 mounted on the stage 4).

In step S302 (coating step), the supply portion 17 applies or arranges an imprint material in, of a plurality of shot regions of the substrate 1, a shot region where a pattern is immediately transferred. Note that in the following description, a “shot region” means a “shot region” where a pattern is immediately transferred, unless otherwise contextualized. The application or arrangement of the imprint material to the shot region of the substrate 1 can be performed by discharging the imprint material from the supply portion 17 while moving the stage 4 (that is, the substrate 1). In step S303, the stage 4 is driven so that the shot region of the substrate 1 moves to immediately below the pattern region 47 of the mold 10. The mold head 11 is driven down by the actuator 15 so that the pattern region 47 comes into contact with the imprint material in the shot region.

In step S304 (alignment step), alignment between the shot region and the pattern region 47 is performed using the alignment detection system 16 in the state in which the imprint material in the shot region of the substrate 1 and the pattern region 47 of the mold 10 are in contact with each other. In this alignment, an alignment error between the shot region and the pattern region 47 is detected using the alignment detection system 16, and the stage 4 can be driven so that the alignment error falls within an allowable range.

In step S305 (curing step), the imprint material is irradiated with curing light from a light source (not shown) via the collimator lens 13 and the mold 10, curing the imprint material. In step S306 (separation step), the mold head 11 is driven above by the actuator 15 so as to separate the pattern region 47 from the cured imprint material in the shot region. As a result, the transfer (imprinting) of the pattern to one shot region is completed.

In step S307, the controller 19 determines whether the pattern of the substrate 1 has been transferred to all shot regions to which the pattern needs to be transferred. If a shot region to which the pattern has not been transferred remains, steps S302 to S306 are executed for the shot region. In step S308, the substrate 1 is unloaded from the stage 4 (more specifically, the chuck device 2 mounted on the stage 4).

If the alignment error between the shot region and the pattern region 47 of the mold 10 is large at the start of step S304 (alignment step), the completion of alignment in step S304 takes time. In steps S302 to S306, therefore, the first and second measurement systems can be used. Alternatively, in steps S302 to S306, the second measurement system out of the first and second measurement systems may be used. Note that in at least steps S301 and S308 out of steps S301 to S308, the stage 4 can be controlled using the first measurement system.

The encoder system serving as the second measurement system is a system that measures a relative position between the mold head 11 and the stage 4, and can include the encoder scales 40 and 41 and the encoder heads 42, 43, 44, and 45, as described above. Based on the measurement result of the relative position between the mold head 11 and the stage 4 that is obtained using the encoder system, the controller 19 can control the position of the stage 4 so that the relative position between the mold head 11 and the stage 4 coincides with a target relative position.

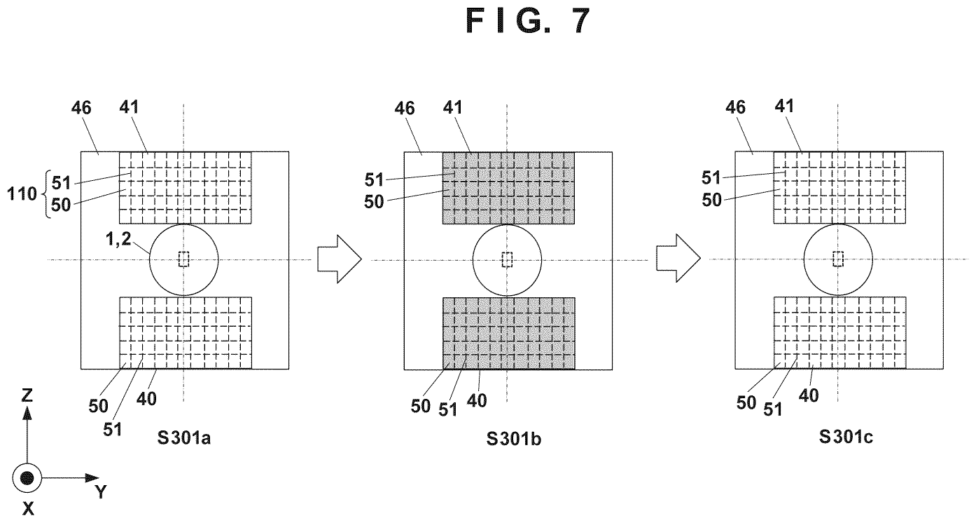

The controller 19 individually controls attractions by the plurality of attractors 50 to suppress a decrease in measurement accuracy caused by deformation of the encoder scales 40 and 41, thereby implementing a high-precision encoder system. A method of controlling the operation states of the plurality of attractors 50 will be exemplified with reference to FIGS. 7, 8, 9, 10, and 11. Note that in each drawing, the white attractor 50 is in the attraction state and the gray attractor 50 is in the non-attraction state.

FIG. 7 exemplifies a method of controlling the operation states of the plurality of attractors 50 accompanying an operation of loading the substrate 1 to the chuck device 2 of the stage 4 and holding the substrate 1 by the stage 4 (chuck device 2) in step S301. In step S301, the controller 19 controls the position of the stage 4 to stop the stage 4 based on the result of measurement by the first measurement system. In step S301, the stage 4 is arranged at a position where the substrate 1 is loaded. In the example of FIG. 7, step S301 includes steps S301a, S301b, and S301c. The substrate 1 may be loaded to the stage 4 in the state of any one of steps S301a, S301b, and S301c.

In step S301a, the controller 19 can control all the attractors 50 to be in the attraction state. In step S301a, therefore, the encoder scales 40 and 41 are held by all the attractors 50. In the state of step S301a, if the purge plate 46 is deformed by heat generated by a linear motor or the like, a stress can be applied to the encoder scales 40 and 41 to deform the encoder scales 40 and 41. If a relative position between the mold head 11 and the stage 4 is measured by the encoder system using the encoder scales 40 and 41 in this state, an error can be generated in the measurement result of the relative position.

To prevent this, in step S301b, the controller 19 can control all the attractors 50 to be in the non-attraction state in a state in which the stage 4 stands still. In step S301b, the encoder scales 40 and 41 are not attracted by any of the attractors 50, the stress applied to the encoder scales 40 and 41 is relaxed, and the deformation of the encoder scales 40 and 41 is reduced.

Then, in step S301c, all the attractors 50 can be controlled to be in the attraction state in the state in which the deformation of the encoder scales 40 and 41 is reduced in step S301b. In step S301c, the encoder scales 40 and 41 are held by all the attractors 50 in the state in which the deformation of the encoder scales 40 and 41 is reduced.

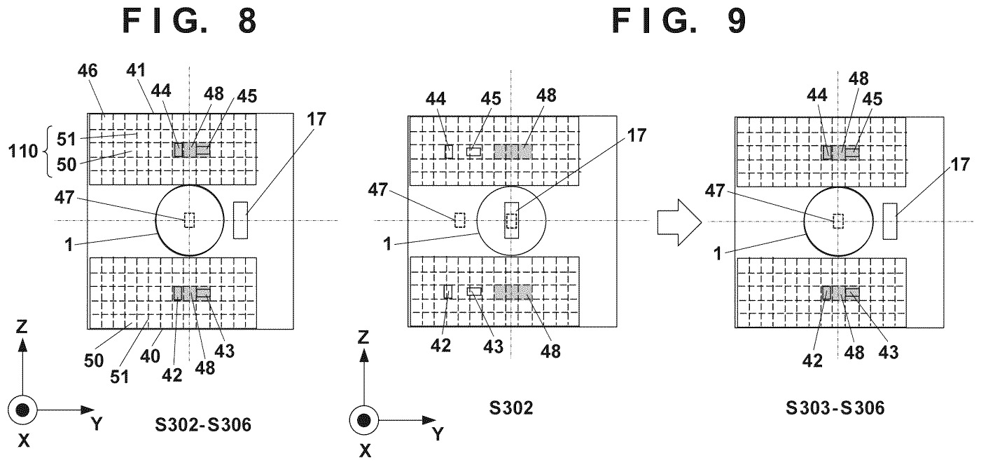

FIG. 8 exemplifies the operation states of the plurality of attractors 50 at a given timing during the execution period of steps S302 to S306. More specifically, FIG. 8 exemplifies the operation states of the plurality of attractors 50 when the pattern region 47 of the mold 10 is brought into contact with the imprint material in the central shot region of the substrate 1, and alignment between the shot region and the pattern region 47 is performed. At this timing, the controller 19 can control the attractors 50 belonging to non-attraction regions 48 facing the encoder heads 42, 43, 44, and 45 to be in the non-attraction state, and the remaining attractors 50 to be in the attraction state. The execution period of steps S302 to S306 can include a period in which the attractors 50 belonging to the non-attraction regions 48 facing the encoder heads 42, 43, 44, and 45 are controlled to be in the non-attraction state, and the remaining attractors 50 are controlled to be in the attraction state. This can suppress deformation of the encoder scales 40 and 41 in the regions facing the encoder heads 42, 43, 44, and 45 while preventing movement of the encoder scales 40 and 41 with respect to the purge plate 46 that is caused by driving the stage 4. In steps S302 to S306, the relative position between the mold head 11 and the stage 4 can be measured and controlled at high accuracy.

FIG. 9 shows states of processing (steps S302 to S306) for transferring a pattern to the central shot region (ith shot region) out of a plurality of shot regions of the substrate 1. The left side of FIG. 9 exemplifies the operation states of the plurality of attractors 50 when the supply portion 17 applies or arranges the imprint material in the ith shot region of the substrate 1 in step S302. At this timing, the ith imprint target shot region can be positioned below the supply portion 17. In the example shown in FIG. 9, the attractors 50 belonging to the non-attraction regions 48 facing the encoder heads 42, 43, 44, and 45 when the ith shot region is positioned below the pattern region 47 are controlled to be in the non-attraction state, and the remaining attractors 50 are controlled to be in the attraction state. This is an advantageous control method in terms of preventing generation of the attractor 50 whose operation state is changed in steps S303 to S306 executed subsequently.

The right side of FIG. 9 exemplifies the operation states of the plurality of attractors 50 in steps S303 to S306. In steps S303 to S306, the controller 19 can control the attractors 50 belonging to the non-attraction regions 48 facing the encoder heads 42, 43, 44, and 45 to be in the non-attraction state, and the remaining attractors 50 to be in the attraction state. This can suppress deformation of the encoder scales 40 and 41 in the regions facing the encoder heads 42, 43, 44, and 45 while preventing movement of the encoder scales 40 and 41 with respect to the purge plate 46 that is caused by driving the stage 4. In steps S302 to S306, the relative position between the mold head 11 and the stage 4 can be measured and controlled at high accuracy.

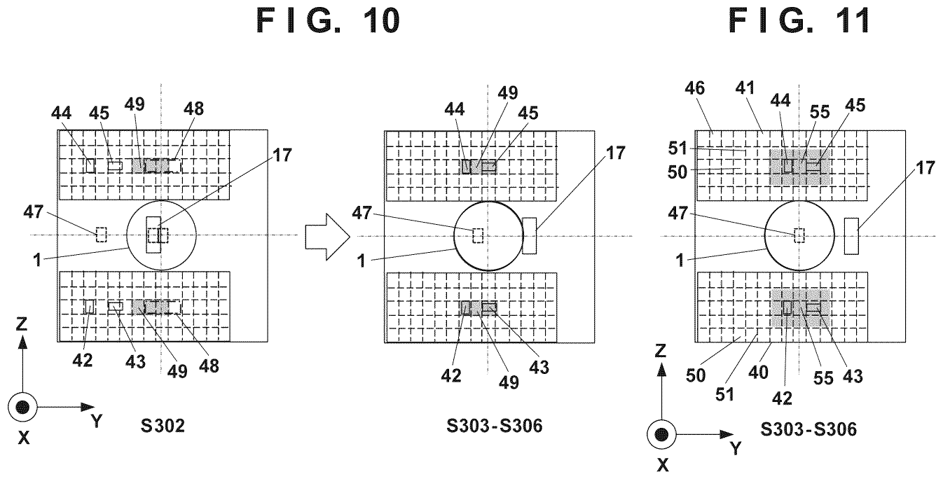

FIG. 10 shows states of processing (steps S302 to S306) for transferring a pattern to the (i+1)th shot region that is a shot region next to the ith shot region (central shot region of the substrate 1) where the pattern has been formed in the processing shown in FIG. 9. In this example, the (i+1)th shot region is a shot region left adjacent to the ith shot region.

The left side of FIG. 10 exemplifies the operation states of the plurality of attractors 50 when the supply portion 17 applies or arranges the imprint material in the (i+1)th shot region of the substrate 1 in step S302. At this timing, the (i+1)th shot region can be positioned below the supply portion 17. In the example shown in FIG. 10, the attractors 50 belonging to non-attraction regions 49 facing the encoder heads 42, 43, 44, and 45 when the (i+1)th shot region is positioned below the pattern region 47 are controlled to be in the non-attraction state, and the remaining attractors 50 are controlled to be in the attraction state. This is an advantageous control method in terms of preventing generation of the attractor 50 whose operation state is changed in steps S303 to S306 executed subsequently.

The right side of FIG. 10 exemplifies the operation states of the plurality of attractors 50 in steps S303 to S306. In steps S303 to S306, the controller 19 can control the attractors 50 belonging to the non-attraction regions 49 facing the encoder heads 42, 43, 44, and 45 to be in the non-attraction state, and the remaining attractors 50 to be in the attraction state. This can suppress deformation of the encoder scales 40 and 41 in the regions facing the encoder heads 42, 43, 44, and 45 while preventing movement of the encoder scales 40 and 41 with respect to the purge plate 46 that is caused by driving the stage 4. In steps S302 to S306, the relative position between the mold head 11 and the stage 4 can be measured and controlled at high accuracy.

Change from the non-attraction regions 48 set for processing of the ith shot region to the non-attraction regions 49 set for processing of the (i+1)th shot region can be performed in parallel to, for example, execution of step S302 with respect to the (i+1)th shot region. This is advantageous for preventing a decrease in throughput caused by changing the non-attraction regions.

In an example, the non-attraction regions are regions facing the encoder heads 42, 43, 44, and 45 in step S304 (alignment step), as described above. In another example, the non-attraction regions can be regions including the regions facing the encoder heads 42, 43, 44, and 45 in step S304 (alignment step). FIG. 11 shows an example in which wide regions including the regions facing the encoder heads 42, 43, 44, and 45 in step S304 (alignment step) are defined as non-attraction regions 55.

The example of FIGS. 9 and 10 can be understood as an operation in a period in which the mold 10 is brought into contact with the imprint material and the imprint material is cured in a state in which the stage 4 is arranged so that the shot region and the pattern region 47 face each other after the imprint material is arranged in a shot region of the substrate 1. The controller 19 can control the plurality of attractors 50 so that the attraction force of the attractor 50 selected from the plurality of attractors 50 becomes weaker than that of the remaining attractors. The selected attractor can be, of the plurality of attractors 50, at least an attractor facing the encoder head.

As exemplified in FIGS. 9 and 10, the dimensions of each attractor 50 can be set to be equal to those of the pattern region of the mold 10 or the shot region of the substrate 1. For example, the array pitch of the attractors 50 can be equal to that of the shot regions. From another viewpoint, the plurality of attractors 50 may be arranged to constitute a plurality of rows and a plurality of columns.

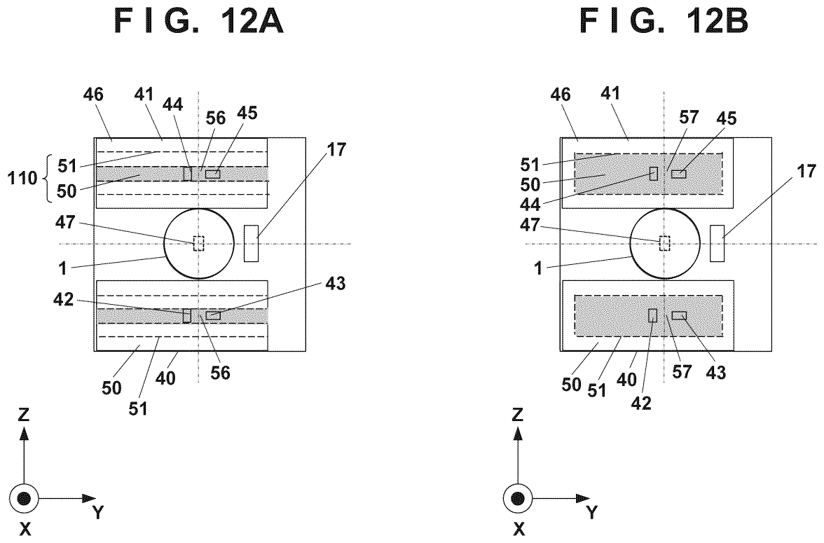

FIG. 12A shows another layout example of the plurality of attractors 50 or non-attraction regions 56. In the example of FIG. 12A, the plurality of attractors 50 include a plurality of strip attractors 50 extending in a direction (X direction) in which the pattern region 47 of the mold 10 and the supply portion 17 are connected. Each attractor 50 constitutes a strip region extending in the X direction. From another viewpoint, the plurality of attractors 50 are laid out to constitute a one-dimensional array, that is, an array in a single direction (Y direction). In the example of FIG. 12A, when the pattern is successively formed in a plurality of shot regions arranged in the X direction, the attractors 50 set to be in the non-attraction state need not be changed (that is, the non-attraction regions 56 need not be changed). For example, the attractors 50 corresponding to the first row are set to be in the non-attraction state, the attractors corresponding to the remaining rows are set to be in the attraction state, and the pattern can be successively formed in a plurality of shot regions constituting the first row. Then, the attractors 50 corresponding to the second row are set to be in the non-attraction state, the attractors corresponding to the remaining rows are set to be in the attraction state, and the pattern can be successively formed in a plurality of shot regions constituting the second row.

FIG. 12B shows still another layout example of the plurality of attractors 50 or non-attraction regions 57. In the example of FIG. 12B, the plurality of attractors 50 include the attractors 50 arranged in the inner region of the scale holding portion 110, and the attractors 50 arranged in the outer region of the scale holding portion 110. The outer region is a region surrounding the inner region. For example, when the inner attractors 50 face all the encoder heads 42, 43, 44, and 45 in the alignment step, like a state shown in FIG. 12B, they can be set to be in the non-attraction state (non-attraction regions 57). In contrast, for example, when at least one of the encoder heads 42, 43, 44, and 45 faces the outer attractors 50 in the alignment step, the outer attractors 50 can be set to be in the non-attraction state (non-attraction regions 57).

As described above, an attraction force generated by each attractor 50 can be, for example, a vacuum attraction force, an electrostatic attraction force, or an electromagnetic attraction force. When the electrostatic attraction force is used, individual electrodes are provided at the respective attractors 50, and supply of charges to the electrodes is individually controlled. When the electromagnetic attraction force is used, coils (electromagnets) are provided at the respective attractors 50, supply of a current to the coils is individually controlled, and a magnetic material is provided on the back surfaces of the encoder scales 40 and 41.

It suffices for the encoder system serving as the second measurement system to measure positions of the stage 4 about three axes (a position in the X direction, a position in the Y direction, and a rotation angle in the θ direction). The encoder system is not limited to the above example. For example, the first encoder measures a relative position only in the X direction, the second encoder measures relative positions in the X and Y directions, and positions about three axes can be obtained based on these measurement results.

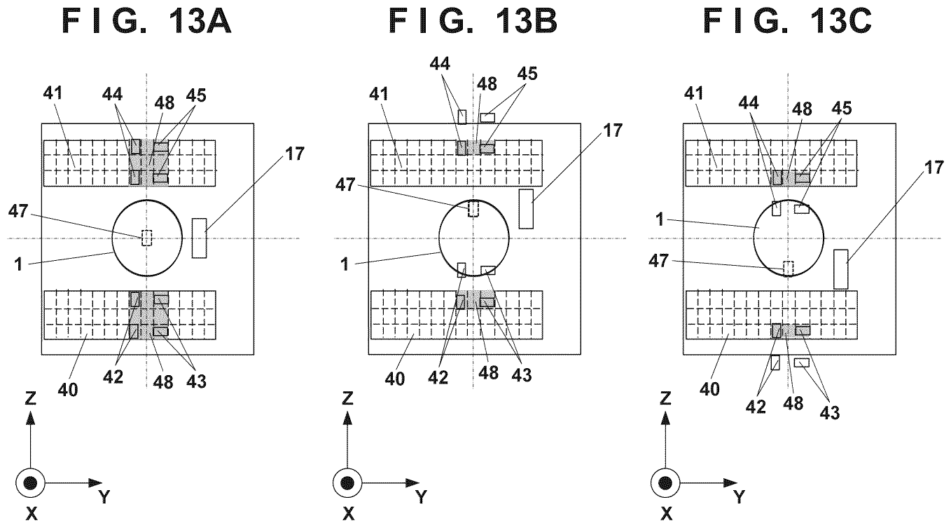

The dimensions, arrangements, and layouts of the encoder scales and encoder heads can be arbitrarily changed. FIGS. 13A to 13C show a modification of the encoder system. The four encoder heads 42, 42, 43, and 43 are assigned to the encoder scale 40 in the first encoder, and the four encoder heads 44, 44, 45, and 45 are assigned to the encoder scale 41 in the second encoder. FIG. 13A shows a state in which a shot region positioned at the center of the substrate 1 is imprinted. FIG. 13B shows a state in which a shot region positioned in the +Y direction from the center of the substrate 1 is imprinted. Each encoder can continue measurement using an encoder head on the −Y direction side. FIG. 13C shows a state in which a shot region positioned in the −Y direction from the center of the substrate 1 is imprinted. Each encoder can continue measurement using an encoder head on the +Y direction side. In this modification, the dimension of each encoder scale in the Y direction is smaller than that of the substrate 1 in the Y direction. In the example of FIGS. 13A to 13C, the attractors facing the encoder heads are controlled to be in the non-attraction state, and the remaining attractors are controlled to be in the attraction state.

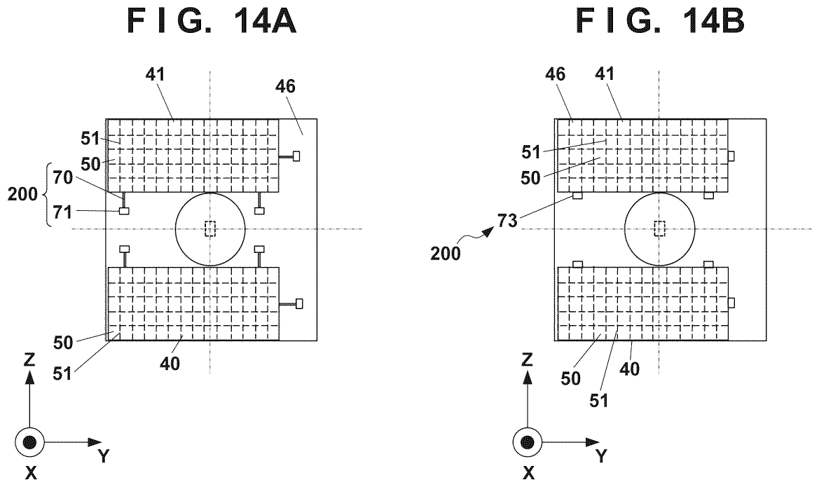

Next, a lithography apparatus 100 and a stage apparatus STM according to the second embodiment will be explained. Matters which will not be mentioned in the second embodiment are pursuant to the first embodiment. FIG. 14A shows the stage apparatus STM in the lithography apparatus 100 in the first arrangement example of the second embodiment. In the second embodiment, the stage apparatus STM includes a second scale holding portion 200, in addition to the first scale holding portion constituted by a plurality of attractors 50. The second scale holding portion 200 has a structure that hardly applies the influence of deformation of a purge plate 46 to encoder scales 40 and 41.

In the first arrangement example of the second embodiment, the second scale holding portion 200 can be configured to hold each of the encoder scales 40 and 41 by a plurality of (three in this case) leaf springs 70. Each leaf spring 70 can have one end connected to the encoder scale, and the other end connected to the purge plate 46 by a leaf spring fixing portion 71. Each leaf spring 70 regulates the position of the encoder scale in the longitudinal direction, and has a degree of freedom in the rotational and widthwise directions. Each of the encoder scales 40 and 41 is held by the three leaf springs 70 about three horizontal axes without transmitting deformation of the purge plate 46 to the encoder scale. In this arrangement, even when all the attractors 50 that attract the encoder scales 40 and 41 are set to be in the non-attraction state in step S301b, the encoder scales 40 and 41 are not misaligned. When the encoder scales 40 and 41 are attracted by one or more attractors 50, they are not misaligned. In this manner, the misalignment of the encoder scales 40 and 41 can be more reliably prevented by providing the second scale holding portion 200 in addition to a first scale holding portion 110.

FIG. 14B shows the stage apparatus STM in the lithography apparatus 100 in the second arrangement example of the second embodiment. In the second arrangement example, the second scale holding portion 200 can be configured to hold the side surface of each of the encoder scales 40 and 41 by being attracted by a plurality of (three in this case) side surface attractors 73. The second scale holding portion 200 can maintain the positions of the encoder scales 40 and 41 in the horizontal direction. The side surfaces of the encoder scales 40 and 41 can have a structure attractable by the side surface attractors 73. The attraction by the side surface attractor 73 can be, for example, vacuum attraction, electrostatic attraction, or electromagnetic attraction. If the second scale holding portion 200 is maintained in the attraction state when setting all the attractors 50 of the first scale holding portion 110 to be in the non-attraction state in step S301b, the misalignment of the encoder scales 40 and 41 can be prevented. The second scale holding portion 200 may be in the non-attraction state in a period in which one or more attractors 50 of the first scale holding portion 110 are set to be in the attraction state.

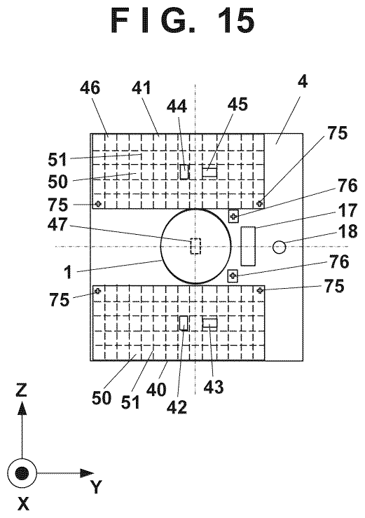

Next, a lithography apparatus 100 and a stage apparatus STM according to the third embodiment will be explained. Matters which will not be mentioned in the third embodiment are pursuant to the first or second embodiment. FIG. 15 shows the stage apparatus STM in the lithography apparatus 100 according to the third embodiment. In the third embodiment, two or more encoder scale reference marks 75 serving as the reference of the position of an encoder are provided, and two or more stage reference marks 76 serving as the reference of the position of a stage 4 are provided on the stage 4.

The position coordinates of each reference mark about two axes in the X and Y directions can be measured by measuring the position of the reference mark by an off-axis detection system 18. Thus, the position coordinates of encoder scales 40 and 41 about three axes in the X, Y, and θ directions can be calculated using the measurement results of the two encoder scale reference marks 75 about two axes in the X and Y directions. Similarly, the position coordinates of the stage 4 about three axes in the X, Y, and θ directions can be calculated from the two stage reference marks 76. The positions of the encoder scales 40 and 41 with respect to the stage 4 can be managed by comparing the position coordinates of the encoder scales 40 and 41 and those of the stage 4 about three axes in the X, Y, and θ directions. According to the third embodiment, in-plane deformation of the encoder scales 40 and 41 can be prevented by controlling the operation state of a plurality of attractors 50 of the encoder scales 40 and 41. In addition, the positions between the encoder scales 40 and 41 and the stage 4 can be managed based on the respective reference marks. As a result, encoder position measurement can be performed at higher accuracy.

An article manufacturing method of manufacturing an article using the lithography apparatus 100 will be described below. The article can be, for example, a semiconductor IC element, a liquid crystal display element, a MEMS, or the like. The article manufacturing method can include a transfer step of transferring a pattern of an original to a substrate using the lithography apparatus, and a processing step of obtaining an article by processing the substrate having undergone the transfer step. When the lithography apparatus is an exposure apparatus, the transfer step can include an exposure step of exposing a substrate (a wafer, a glass substrate, or the like) coated with a photosensitive agent, and a step of developing the substrate (photosensitive agent) having undergone the exposure step. When the lithography apparatus is an imprint apparatus, the transfer step can include a contact step of bringing the original into contact with an imprint material on the substrate, a curing step of curing the imprint material, and a separation step of separating the original from the cured imprint material. The processing step can include, for example, etching, resist removal, dicing, bonding, and packaging.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-138202, filed Aug. 28, 2023, which is hereby incorporated by reference herein in its entirety.

What is claimed is:

1. A lithography apparatus that transfers a pattern of an original to a substrate, comprising:
a stage mechanism including a stage configured to hold the substrate; and
an encoder system including an encoder head and an encoder scale,
wherein the stage includes a scale holding portion configured to hold the encoder scale by an attraction force, and
the scale holding portion includes a plurality of attractors capable of individually controlling attraction.

2. The apparatus according to claim 1, further comprising a controller configured to control an operation state of each of the plurality of attractors in accordance with a position of the stage.

3. The apparatus according to claim 2, wherein the substrate has a plurality of shot regions, and the controller individually controls the operation state of each of the plurality of attractors in accordance with a position of a shot region where the pattern is formed.

4. The apparatus according to claim 3, wherein the controller controls an attractor selected from the plurality of attractors to be in a non-attraction state, and
the selected attractor includes, of the plurality of attractors, an attractor facing the encoder head in a predetermined period.

5. The apparatus according to claim 3, wherein the controller controls an attraction force of an attractor selected from the plurality of attractors to be weaker than an attraction force of remaining attractors, and
the selected attractor includes, of the plurality of attractors, an attractor facing the encoder head in a predetermined period.

6. The apparatus according to claim 3, wherein the controller controls an attraction force of an attractor selected from the plurality of attractors to be weaker than an attraction force of remaining attractors, and
the selected attractor is, of the plurality of attractors, an attractor arranged in a region including a region facing the encoder head in a predetermined period.

7. The apparatus according to claim 3, wherein the controller controls all the plurality of attractors to be in a non-attraction state in a state in which the stage stands still, and then controls all the plurality of attractors to be in an attraction state.

8. The apparatus according to claim 1, wherein the plurality of attractors are arranged to constitute a plurality of rows and a plurality of columns.

9. The apparatus according to claim 1, wherein the plurality of attractors are arranged to constitute a plurality of strip regions.

10. The apparatus according to claim 1, wherein the scale holding portion includes an inner region, and an outer region surrounding the inner region, and
the plurality of attractors include one attractor constituting the inner region, and one attractor constituting the outer region.

11. The apparatus according to claim 1, further comprising a second scale holding portion configured to regulate a position of the encoder scale in a horizontal direction.

12. The apparatus according to claim 1, wherein the encoder scale has a first reference mark, and
the stage has a second reference mark.

13. The apparatus according to claim 1, wherein the lithography apparatus is configured to bring the original into contact with an imprint material on the substrate and cure the imprint material, thereby transferring the pattern of the original to the substrate.

14. The apparatus according to claim 13, further comprising a controller configured to, in a period in which the original is brought into contact with the imprint material and the imprint material is cured in a state in which the stage is arranged to make a shot region of the substrate face a pattern region of the original after the imprint material is arranged in the shot region, control the plurality of attractors to set an attraction force of an attractor selected from the plurality of attractors to be weaker than an attraction force of remaining attractors,
wherein the selected attractor is, of the plurality of attractors, at least an attractor facing the encoder head in the state.

15. The apparatus according to claim 13, further comprising a supply unit configured to supply the imprint material to a shot region of the substrate,
wherein the plurality of attractors include a plurality of strip attractors extending in a direction in which the pattern region of the original and the supply unit are connected.

16. The apparatus according to claim 1, wherein the lithography apparatus is constituted as an exposure apparatus configured to transfer the pattern of the original to the substrate by projecting the pattern of the original to the substrate by a projection optical system.

17. An article manufacturing method comprising:
transferring a pattern of an original to a substrate using a lithography apparatus defined in claim 1; and
processing the substrate having undergone the transferring, thereby obtaining an article.

18. A stage apparatus comprising a stage configured to hold a substrate and an encoder scale,
the stage including a scale holding portion configured to hold the encoder scale by an attraction force, and
the scale holding portion including a plurality of attractors capable of individually controlling attraction.
